(19) United States
(12) Patent Application Publication
(10) Pub. No.: US 2009/0151896 A1
(43) Pub. Date: Jun. 18, 2009

(54) HEAT DISSIPATION DEVICE

(75) Inventors: CHUN-CHI CHEN, Tu-Cheng (TW); MIN LI, Shenzhen (CN); HONG-CHENG YANG, Shenzhen (CN)

Correspondence Address: PCE INDUSTRY, INC.;ATT. Steven Reiss, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/955,318

(22) Filed: Dec. 12, 2007

(51) Int. Cl. H05K 7/20; F28F 7/00

(52) U.S. Cl. 165/80.3

(57) ABSTRACT

A heat dissipation device includes a heat sink and a wire clip. The heat sink has a base plate and a plurality of parallel fins arranged on the base plate. The heat sink defining a plurality lengthways channels between every two neighboring fins and a plurality of transverse channels perpendicular to the lengthways channels. The clip comprises a main body spanning on the base plate of the heat sink and two latching legs extending contrary from two opposite ends of the main body. The main body comprises a pressing section received in the lengthways channels and two pivoting sections extending from two opposite ends of the pressing section and received in the transverse channels. The two latching legs are located at the two opposite sides of the heat sink.

### BACKGROUND OF THE INVENTION

1. Field of the Invention

The present invention relates to a heat dissipation device, and more particularly to a heat dissipation device having a clip assembly which can readily and securely attach a heat sink to an electronic component.

2. Description of Related Art

A heat sink is usually placed in thermal contact with an electronic package such as a central processing unit (CPU), and transfers heat through conduction away from the electronic package so as to prevent over-heating of the electronic package. Usually, a heat sink is secured to an electronic package by using a clip.

U.S. Pat. No. 6,518,507 B1 shows a heat sink assembly including a heat sink and a clip securing the heat sink to an electronic component mounted on a printed circuit board. The heat sink comprises a base and a plurality of fins extending from the base. A plurality of receiving grooves is defined between adjacent fins. Two neighboring fins located at two lateral sides of the groove in the middle of the heat sink project a pair of bulges on opposite inner walls thereof. The clip spans across the groove in the middle portion of the heat sink with a positioning portion received in the middle of the heat sink in a manner such that the positioning portion abuts against the bulges and the base of the heat sink. Two arms which extend from two ends of the positioning portion, have a pair of hooks engaging with the printed circuit board, thereby securing the heat sink to the printed circuit board.

The clip can prevent the heat sink from sliding with respect to the printed circuit board along an elongated direction perpendicular to the grooves of the heat sink. However, the heat sink is prone to move along the direction where the grooves extend, when the heat sink is subject to vibration. This makes the heat sink not able to have an intimate contact with the electronic component, whereby, the heat generated by the electronic component cannot be effectively dissipated by the heat sink.

What is needed, therefore, is a heat dissipation device having an improved clip assembly which can overcome the above problem.

### SUMMARY OF THE INVENTION

A heat dissipation device for removing heat from electronic component mounted on a printed circuit board, the heat dissipation device includes a heat sink and a wire clip securing the heat sink to the printed circuit board. The heat sink has a base plate in contact with the electronic component and a plurality of parallel fins arranged on the base plate. The heat sink defining a plurality lengthways channels between every two neighboring fins and a plurality of transverse channels perpendicular to the lengthways channels. The clip comprises a main body spanning on the base plate of the heat sink and two latching legs extending contrary from two opposite ends of the main body. The main body comprises a pressing section received in the lengthways channels and two pivoting sections extending from two opposite ends of the pressing section and received in the transverse channels. The two latching legs are located at the two opposite sides of the heat sink.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an assembled view of a heat dissipation device in accordance with a preferred embodiment of the present invention;

FIG. 2 is an exploded, isometric view of FIG. 1;

FIG. 3 is a side view of FIG. 1; and

FIG. 4 is a top view of FIG. 1.

### DETAILED DESCRIPTION OF THE INVENTION

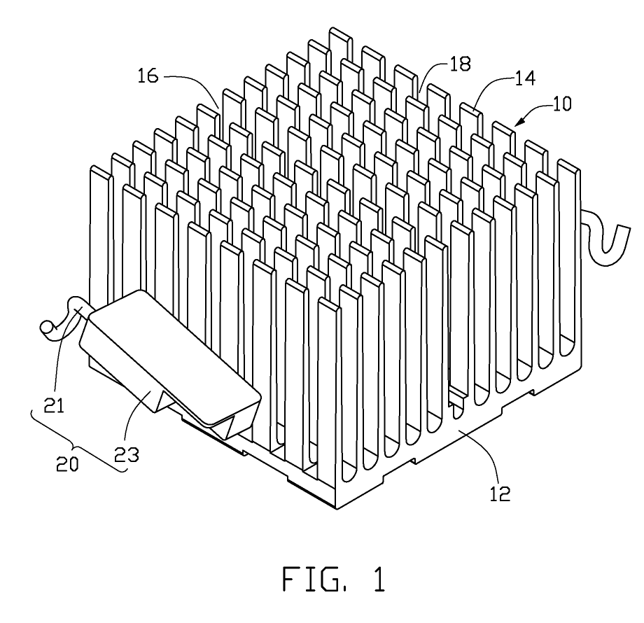

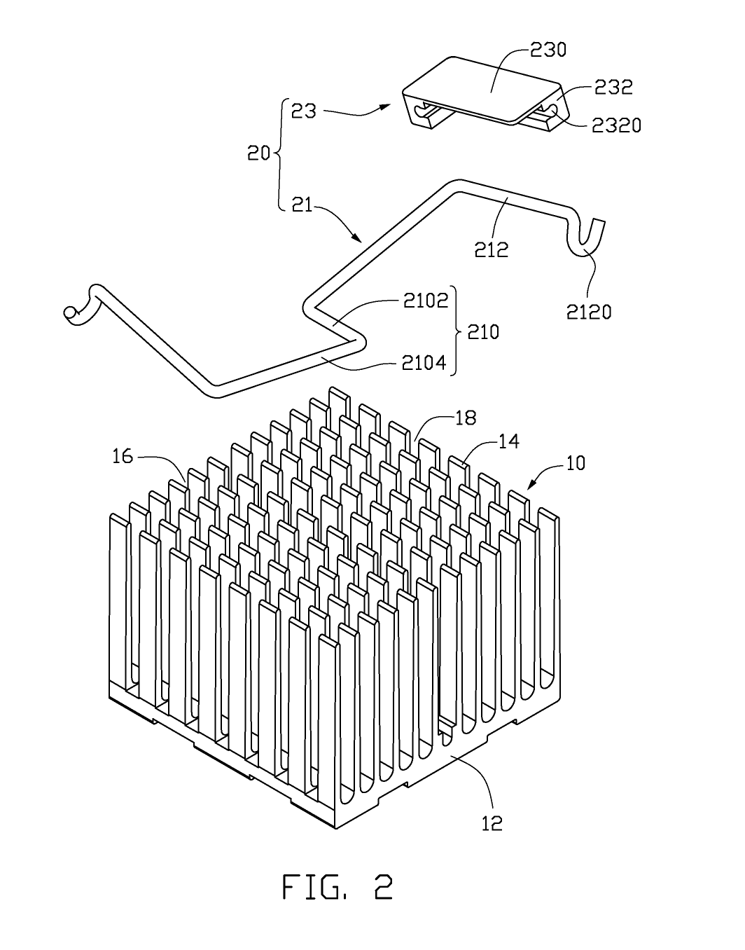

Referring to FIGS. 1-2, a heat dissipation device in according with a preferred embodiment of the invention is shown. The heat dissipation device includes a heat sink 10 having a bottom surface for contacting with an electronic component (not shown) mounted on a printed circuit board (not shown) and a clip assembly 20 spanning on the heat sink 10 to secure the heat sink 10 onto the printed circuit board so that the heat sink 10 can have an intimate contact with the electronic component.

The heat sink 10 comprises a rectangular base plate 12 having a bottom face for thermally contacting with the electronic component, and a plurality of fins 14 integrally extending upwardly and perpendicularly from a top face of the base plate 12. The fins 14 are parallel to front and rear sides of the heat sink 10 and spaced from each other with a predetermined distance. The heat sink 10 defines a plurality of lengthways channels 16 and a plurality of spaced transverse channels 18 perpendicular to the lengthways channels 16 between the fins 14. The fins 14 are cut into a plurality of averagely parts by the transverse channels 18. Each part of the fins 14 is rectangular in cross section.

The clip assembly 20 is disposed in the transverse channels 18 of the heat sink 10 and rests on the base plate 12 of the heat sink 10. The clip assembly 20 comprises a wire clip 21 and an operating member 23 mounted on the wire clip 21 for facilitating operation of the wire clip 21. The wire clip 21 is made from a single piece of spring wire and comprises a main body 210 and two latching legs 212 extending obliquely and oppositely from two opposite ends of the main body 210. The main body 210 comprises a pressing section 2102, and two pivoting sections 2104 extending from two ends of the pressing section 2102. The pressing section 2102 is received in a middle portion of a lengthways channel 16 in a middle portion of the heat sink 10 and presses downwardly on the bottom surface of the base plate 12. The two pivoting sections 2104 perpendicular to the pressing section 2102 extend obliquely and upwardly from two opposite ends of the pressing section 2102 and are received in two of the spaced transverse channels 18. The two latching legs 212 are parallel to each other and extend oppositely and perpendicularly from two respective free ends of the two pivoting sections 2104 of the main body 210. Each distal end of the latching legs 212 is provided with a hook 2120 for engaging with one of rings (not shown) mounted on the printed circuit board. The hook 2120 is formed by bending the distal end of the latching leg 212 downwardly and then upwardly so that the hook 2120 has a U-shaped configuration.

The operating member 23, which is integrally formed by plastic injection molding, comprises a top plate 230 and two sidewalls 232 extending perpendicularly from two neighboring edges of the top plate 230. The two sidewalls 232 are separated from each other and each define a corresponding engaging groove 2320 therein. The two engaging grooves 2320 are parallel to the top plate 230 and include a short one in the side wall 232 extending from the short side edge of the top plate 230 and a long one in the sidewall 232 extending from the long side edge of the top plate 230. The operating member 23 is coupled to one of the latching legs 212 of the wire clip 21 by interferentially fitting a portion of the pivoting section 2104 and a portion of the latching leg 212 respectively into the short and long engaging grooves 2320.

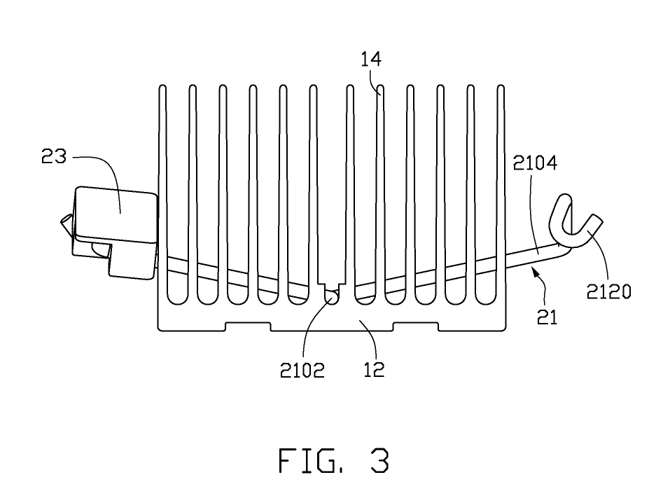

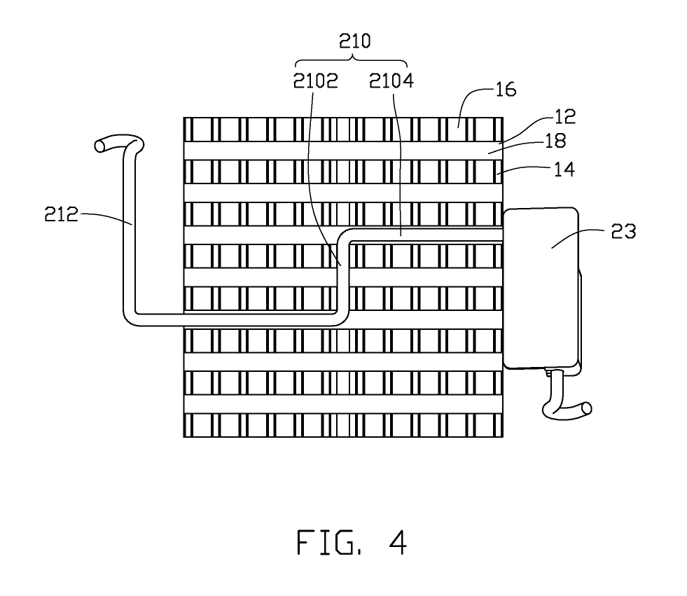

As shown in FIG. 3 and FIG. 4, to secure the heat sink 10 on the printed circuit board, the main body 210 of the wire clip 21 is placed in the lengthways and transverse channels 16, 18 of the heat sink 10, the two opposite latching legs 212 parallel to the fins 14 are respectively located at front and rear sides of the heat sink 10. One of the latching legs 212 without the operating member 23 is rotated downwardly relative to the pressing section 2102 to make the hook 2120 of the latching leg 212 to reach and engage with the corresponding ring mounted on the printed circuit board. The operating member 23 is pressed downwardly to force another latching leg 212 to rotate downwardly to engage into the corresponding ring. As the two latching legs 212 are rotated downwardly to make the hooks 2120 of the two latching legs 212 engaged into the two respective rings, the pivoting sections 2104 of the main body 210 are in a torsional deformation and the pressing section 2102 presses the base plate 12 of the heat sink 10 downwards, the heat sink 10 is thus securely mounted on the printed circuit board.

In use of the clip assembly 20, the pressing section 2102 and the two pivoting sections 2104 of the main body 210 of the wire clip 21 are respectively fitly received in the lengthways and the transverse channels 16, 18 that are perpendicular to each other, whereby the wire clip 21 is able to securely lock the heat sink 10 onto the printed circuit board and also restrict it from moving lengthways or transversely.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device adapted for removing heat from an electronic component mounted on a printed circuit board, the heat dissipation device comprising:
a heat sink having a base plate and a plurality of parallel fins arranged on the base plate, the heat sink defining a plurality lengthways channels and a plurality of transverse channels perpendicular to the lengthways channels between the fins; and
a clip comprising a main body spanning on the base plate of the heat sink and two latching legs extending oppositely from two free ends of the main body, the main body comprising a pressing section received in the lengthways channels and two pivoting sections extending from two opposite ends of the pressing section and received in the transverse channels, the two latching legs located at the two opposite sides of the heat sink.

2. The heat dissipation device as claimed in claim 1, wherein the two pivoting sections are perpendicular to the pressing section and oblique to a top surface of the base plate.

3. The heat dissipation device as claimed in claim 1, wherein the two latching legs are perpendicular to the pivoting sections of the main body and parallel to the fins.

4. The heat dissipation device as claimed in claim 1, wherein the transverse channels are perpendicular to the fins and cut the fins into a plurality of averagely parts.

5. The heat dissipation device as claimed in claim 1, wherein the latching legs each forms a hook at distal end thereof and is rotated downwardly relative to the pivoting sections to force the hook engage with the printed circuit board.

6. The heat dissipation device as claimed in claim 1, further comprising an operating member which is mounted on one of the latching legs.

7. The heat dissipation device as claimed in claim 6, wherein the operating member comprises a top plate and two sidewalls extending perpendicularly from two neighboring edges of the top plate.

8. The heat dissipation device as claimed in claim 7, wherein the two sidewalls respectively engage with one of the latching legs and the main body of the clip.

9. The heat dissipation device as claimed in claim 1, wherein the base plate is rectangular and the fins extend perpendicularly from a top surface of the base plate.

10. The heat dissipation device as claimed in claim 9, wherein the fins and the lengthways channels are parallel to two opposite sides of the base plate.

11. A heat dissipation device for removing heat from an electronic component mounted on a printed circuit board, the heat dissipation device comprising:
a heat sink has a base plate and a plurality of parallel fins extending upwardly from a top surface of the base plate, the heat sink defining a plurality lengthways channels between every two neighboring fins and a plurality of transverse channels unparallel to the lengthways channels; and
a clip comprising a main body disposed on the base plate and two latching legs extending oppositely from two free ends of the main body, one part of the main body being received in the lengthways channels and other part of the main body being received in the transverse channels, the two latching legs located at two opposite sides of the heat sink.

12. The heat dissipation device as claimed in claim 11, wherein the main body comprises a pressing section received in the lengthways channels and two pivoting sections extending contrary from two opposite ends of the pressing section and received in the transverse channels.

13. The heat dissipation device as claimed in claim 12, wherein the two pivoting sections are perpendicular to the pressing section and oblique to a top surface of the base plate.

14. The heat dissipation device as claimed in claim 12, wherein the two latching legs are perpendicular to the pivoting sections of the main body and parallel to the fins.

15. The heat dissipation device as claimed in claim 12, wherein the transverse channels are perpendicular to the fins and cut the fins into a plurality of averagely parts.

16. The heat dissipation device as claimed in claim 12, wherein the latching legs each form a hook at distal end thereof and are rotated downwardly relative to the pivoting sections to force the hook to engage with the printed circuit board.

17. A heat dissipation device comprising:
a heat sink having a base plate, a plurality of fins extending upwardly from the base plate, a plurality of first and second channels extending through the fins, the second channels interlaced with the first channels; and
a clip having a pressing section fitted in one of the first channels and two pivoting sections extend obliquely and upwardly from two opposite ends of the pressing section, the two pivoting sections received in two of spaced second channels, a pair of latching legs extending from opposite ends of the pivoting sections, each leg having a hook formed at a free end thereof, the hook being adapted for engaging with a printed circuit board thereby securing the heat sink to the printed circuit board.

18. The heat dissipation device as claimed in claim 17, wherein the two pivoting sections are perpendicular to the pressing section.
